(19) United States
(12) Patent Application Publication
(10) Pub. No.: US 2014/0049144 A1
(43) Pub. Date: Feb. 20, 2014

(54) SERVER WITH CABLE ORGANIZER

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: YU HAN, Shenzhen (CN); HAN-BING ZHANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/684,186

(22) Filed: Nov. 22, 2012

(30) Foreign Application Priority Data
Aug. 14, 2012 (CN) 2012102878670

(51) Int. Cl. H05K 5/02

(52) U.S. Cl. CPC H05K 5/0247
USPC 312/223.6

(57) ABSTRACT

A server includes a chassis and two cable organizers. The chassis includes an end wall, and a number of cables connected to an outer surface of the end wall. The cable organizers are mounted to opposite ends of the end wall. An opening is defined in each cable organizer, for allowing a palm of an operator to extend through. A number of substantially C-shaped cutouts is defined in each cable organizer in communication with the corresponding opening, for allowing the cables to engage in.

### BACKGROUND

1. Technical Field

The present disclosure relates to a server having a cable organizer.

2. Description of Related Art

Many servers may be installed together in the same rack. Each server will have a number of cables connected to it. Therefore, many cables easily become intertwined so that when a server is pulled out of the cabinet, some of the intertwined cables may be inadvertently unplugged.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a server.

FIG. 2 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

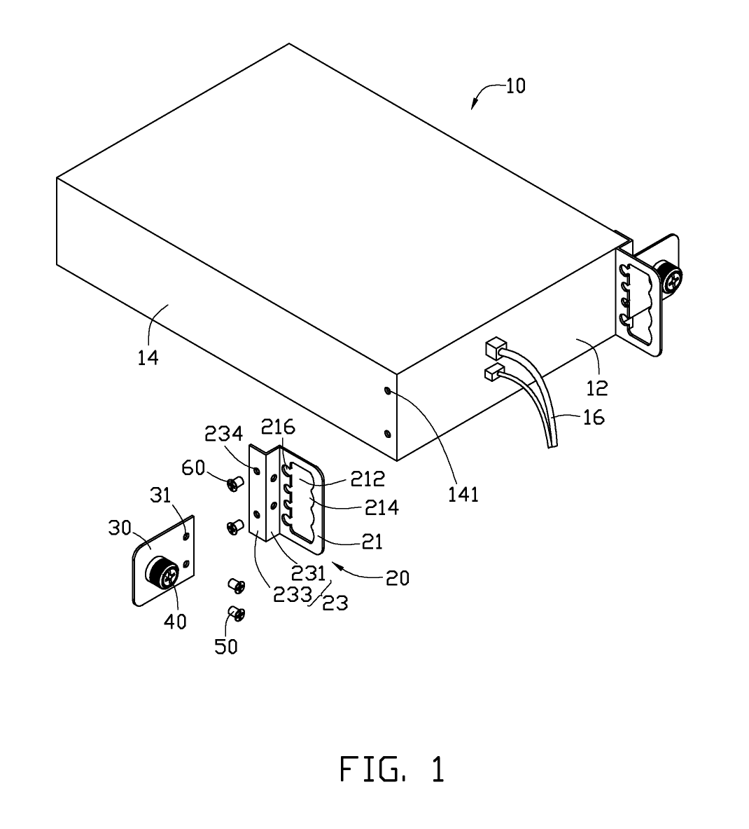

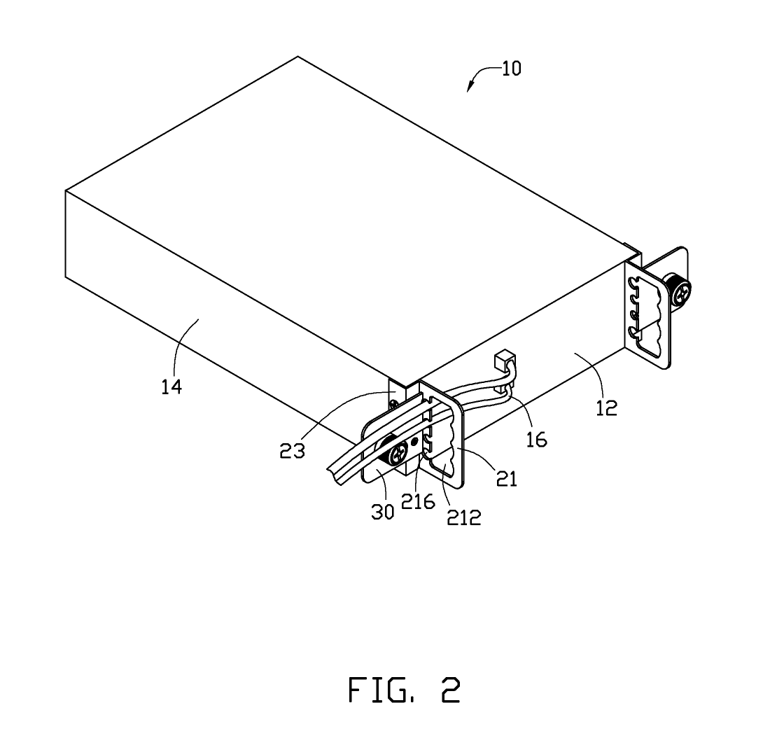

FIGS. 1 and 2 show an embodiment of a server. The server includes a chassis 10, two cable organizers 20, two fixing tabs 30, and two fasteners 40.

The chassis 10 includes an end wall 12, and two sidewalls 14 extending rearward from opposite ends of the end wall 12 in a perpendicular manner. A plurality of different sized cables 16 is connected to the front side of the end wall 12. Two threaded holes 141 are defined in the front end of each sidewall 14.

Each cable organizer 20 includes a main body 21, and a fixing portion 23 formed on the rear end of the main body 21. An opening 212 is defined in a middle of the main body 21, to allow a hand of an operator to extend through. A plurality of arc-shaped cutouts 214 is defined in the main body 21 in front of the opening 212 and in communication with the opening 212, to allow fingers of the operator to engage in. A plurality of different sized substantially C-shaped cutouts 216 is defined in the main body 21 behind the opening 212 and in communication with the opening 212, to allow the cables 16 to extend through. The fixing portion 23 includes a connecting plate 231 connected to the rear end of the main body 21 in a perpendicular manner, and a fixing plate 233 extending rearward from a side of the connecting plate 231 away from the main body 21 in a perpendicular manner. Each of the connecting plate 231 and the fixing plate 233 defines two through holes 234.

The fasteners 40 are respectively extended through the middles of the fixing tabs 30. Two through holes 31 are defined in an end of each fixing tab 30.

In assembly, four rivets 50 respectively extend through the through holes 31 of the fixing tabs 30, and engage in the through holes 234 of the connecting plates 231, to mount the fixing tabs 30 to the cable organizers 20. The fixing portions 23 are respectively engaged with two front corners of the chassis 10. The connecting plates 231 respectively abut opposite ends of the end wall 12. The fixing plates 233 respectively abut the front ends of the sidewalls 14, with the through holes 234 of the fixing plates 233 respectively aligning with the threaded holes 141. Four screws 60 respectively extend through the through holes 234 of the fixing plates 233, and engage in the corresponding threaded holes 141, to mount the cable organizers 20 to opposite ends of the front end of the chassis 10. Thereby, the server is assembled.

In use, the cables 16 extend through the opening 212 of one of the cable organizers 20, and are engaged in the corresponding C-shaped cutouts 216 of the cable organizer 20, according to the sizes of the cables 16 and the C-shaped cutouts 216.

The server is mounted in a rack by the fasteners 40 or two slide rails (not shown). The cables 16 are orderly extended through the corresponding cable organizer 20, and will not intertwine with cables of other servers in the rack. When the server is pushed into or pulled out of the rack, an operator can grasp the cable organizers 20, which will make the operation easy.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server, comprising:
a chassis comprising an end wall, and a plurality of cables connected to an outer surface of the end wall; and
two cable organizers mounted to opposite ends of the end wall, wherein an opening is defined in each cable organizer for allowing a palm of an operator to extend through; and a plurality of substantially C-shaped cutouts is defined in each cable organizer in communication with the corresponding opening, for allowing the cables to engage in.

2. The server of claim 1, wherein the C-shaped cutouts of each cable organizer have different sizes.

3. The server of claim 1, wherein a plurality of arc-shaped cutouts is defined in each cable organizer in communication with the corresponding opening, for allowing fingers of the operator to engage in.

4. The server of claim 3, wherein the C-shaped cutouts are defined in the cable organizers behind the corresponding openings, and the arc-shaped cutouts are defined in the cable organizers in front of the corresponding openings.

5. The server of claim 4, wherein each cable organizer comprises a main body, and a fixing portion formed on a rear end of the main body and connected to the chassis, the opening, the C-shaped cutouts, and the arc-shaped cutouts are defined in the main body.

6. The server of claim 5, wherein the chassis further comprises two sidewalls extending rearward from the opposite ends of the end wall in a perpendicular manner, each fixing portion comprises a connecting plate connected to a rear end of the main body in a perpendicular manner, and a fixing plate extending rearward from a side of the connecting plate away from the main body in a perpendicular manner, the fixing plates of the cable organizers are respectively fixed to front ends of the sidewalls, and the connecting plates of the cable organizers abut the opposite ends of the end wall.

7. The server of claim 1, wherein a fixing tab is mounted to a side of each cable organizer away from the cable organizer, two fasteners respectively extend through the fixing tabs.
